(19) United States
(12) Patent Application Publication
(10) Pub. No.: US 2013/0139376 A1
(43) Pub. Date: Jun. 6, 2013

(54) METHOD FOR MANUFACTURING A CONCENTRATED-PHOTOVOLTAIC PANEL

(71) Applicants: Jean Edouard De Salins, Paris (FR); François Dumenil, Chaume en Brie (FR); Paul Bellavoine, Paris (FR)

(72) Inventors: Jean Edouard De Salins, Paris (FR); François Dumenil, Chaume en Brie (FR); Paul Bellavoine, Paris (FR)

(21) Appl. No.: 13/643,983

(22) PCT Filed: Apr. 28, 2011
(86) PCT No.: PCT/EP2011/056796

§ 371 Date: Feb. 4, 2013

(30) Foreign Application Priority Data
Apr. 28, 2010 (FR) 1053272

(51) Int. Cl. H01L 31/00; H01L 31/18; B23P 19/10

(52) U.S. Cl. CPC H01L 31/18
USPC 29/592.1; 29/760

(57) ABSTRACT

The invention relates to a method for manufacturing a concentrated-photovoltaic panel (1), said panel (1) including: a back surface (11) designed to hold a series of photovoltaic modules (20) in position; a front surface (12); a lower part (13a, 13′a) of a mounting (13, 13′) attached to the front surface, said mounting (13, 13′) being designed to hold a series of light-energy concentration systems (30) in position, such that each concentration system (30) is aligned with at least one associated photovoltaic module (20); and lateral walls (16) connecting the back surface (11) and the front surface (12) so as to define a closed box (10); the method being characterized in that the respective position of the photovoltaic modules (20) is fixed in space with respect to the lower part (13a) of the mounting (13, 13′), when the front surface (12), the lateral walls (16) and the back surface (12) of the box (10) are assembled with the photovoltaic modules (20) and the lower part (13a, 13′a) of the mounting (13, 13′).

The invention relates to concentrated photovoltaic solar technology.

More particularly, the invention relates to concentrated photovoltaic panels.

A concentrated photovoltaic panel is a device for converting light energy into electric energy. It comprises especially a series of photovoltaic receivers which are semi-conducting electronic components adapted to generate an electric current when exposed to light transmitted by a light concentration system, generally a lens or a mirror.

To optimise the light flow transmitted by concentration systems, photovoltaic receivers must be positioned very precisely in the focal centre of said systems.

It has therefore been proposed to use caissons to precisely position photovoltaic receivers relative to the concentration systems. Such caissons must be robust, sealed, insensitive to condensation phenomena and stable over time, and generally comprise a rear face adapted to receive at least one photovoltaic receiver and a front face, adapted to receive at least one light energy concentration system. The front face and the rear face are connected together by lateral walls so as to define an enclosure. The concentration systems and the photovoltaic receivers are fixed on the front and rear faces such that each receiver is positioned in the focal centre of the concentration system with which it is associated.

To guarantee proper positioning of the receivers and concentration systems as well as their stability over time, the front and rear faces of the caisson are machined with a high degree of precision. In addition, after the receivers and the concentration systems have been fixed in the caisson, the latter is generally stressed to adjust their relative positioning and guarantee their alignment. This adjustment can be performed especially by means of precision cameras.

Finally, the caisson is generally made in a clean room to limit defects due to the presence of dust and/or variations in temperature.

This manufacturing process is therefore delicate and highly restrictive, to the extent where it requires tools and specific premises. Its cost is also high, since the quality of the panel obtained depends not only on the initial manufacturing finishing and precision of the caisson, but also on stresses applied to it after fixing of the concentration systems and receivers to readjust their alignment.

Another drawback to existing processes is that the resulting panels are difficult to transport and install at their place of use, especially due to their manufacturing complexity and their fragility.

The aim of the invention therefore is to propose a manufacturing process of a concentrated photovoltaic panel which costs less relative to conventional processes, which may be easily transported to the place of use, and which is simple to execute from the industrial viewpoint.

Another aim of the invention is to propose a manufacturing process for producing a photovoltaic panel which is robust, sealed, and insensitive to condensation issues, and has good stability over time and good energetic output.

For this, the invention proposes a manufacturing process of a concentrated photovoltaic panel, said panel comprising:
a rear face adapted to fix in position a series of photovoltaic modules;
a front face,
a lower part of a support fixed on the front face, said support being adapted to fix in position a series of light energy concentration systems, such that each concentration system is aligned with at least one photovoltaic module with which it is associated; and
lateral walls connecting the rear face and the front face so as to define a closed caisson;

the process being characterised in that the photovoltaic modules are spatially fixed so as to be positioned relative to the lower part of the support, while the front face, the lateral walls and the rear face of the caisson are assembled with the photovoltaic modules and the lower part of the support.

Some preferred but not-limiting aspects of the manufacturing process according to the invention are the following:
the photovoltaic modules are spatially positioned relative to each other and relative to the lower part of the support; and
the front face is assembled with the lower part of the support on the one hand, and the rear face with the photovoltaic modules on the other hand, by keeping the photovoltaic modules spatially positioned relative to the position of the concentration systems in the lower part;
it also comprises the application of an adjustment joint in at least one of the zones of the following group:
   between all or some of the photovoltaic modules and the rear face of the caisson,
   between the rear face of the caisson and the flanks of the caisson,
   between the front face of the caisson and the lower part;
it also comprises a subsequent step for fixing the light concentration systems on the lower part;
the support is a plate made of glass on which is fixed a film comprising the concentration systems, and in that the lower part is the lower face of said plate;
the photovoltaic modules are spatially fixed and positioned relative to the lower part of the support part:
positioning of the lower part of the support on a base; and

positioning of the modules on calibration feet, each calibration foot being held fixed relative to the base during application of the front face on the lower part and arranged such that when the concentration systems are mounted on the lower part the photovoltaic modules are in their respective focal centre;
the photovoltaic modules are spatially positioned and relative to the lower part:
   positioning of the lower part of the support on a base; and
   positioning of the modules on a calibration chassis, the calibration chassis itself being put in position relative to the base and arranged such that when the faces and lateral walls of the caisson are assembled with the modules and the lower part of the support the photovoltaic modules are in the respective focal centre of said concentration systems;
the photovoltaic modules are fixed on the rear face of the caisson before being positioned on the calibration chassis;
it also comprises a step for fixing concentration systems on the lower part of the support prior to positioning of said lower part on the base; and
it also comprises the positioning of the chassis relative to the base by means of a calibration foot.

According to a second aspect, the invention proposes an assembly table for manufacturing a concentrated photovoltaic panel, the panel comprising:
a rear face adapted to fix in position a series of photovoltaic modules;
a front face, supporting a lower part of a support; and
lateral walls connecting the rear face and the front face so as to define a closed caisson;

the assembly table comprising:
a base adapted to receive the lower part of the support, and
calibration means intended to receive and keep in position the photovoltaic modules relative to the lower part of the support,

and being characterised in that the calibration means are spatially positioned relative to the base during assembly of the lateral walls and of the faces of the caisson with the photovoltaic modules (20) and the lower part.

Some preferred aspects but non-limiting of the assembly table according to the invention are the following:
the calibration means comprise a chassis, calibration feet and a mounting support, the calibration feet and the mounting support being adapted to position the chassis relative to the base;
the chassis is adapted to receive the rear face of the caisson pre-fitted with the photovoltaic modules, while the base is adapted to receive the front face;
the base exhibits resistance to deformations greater than that of the front face and of the lower part; and
the calibration feet are fixed on the base.

Other characteristics, aims and advantages of the present invention will emerge more clearly from the following detailed description, and with respect to the attached diagrams given by way of non-limiting examples and in which:

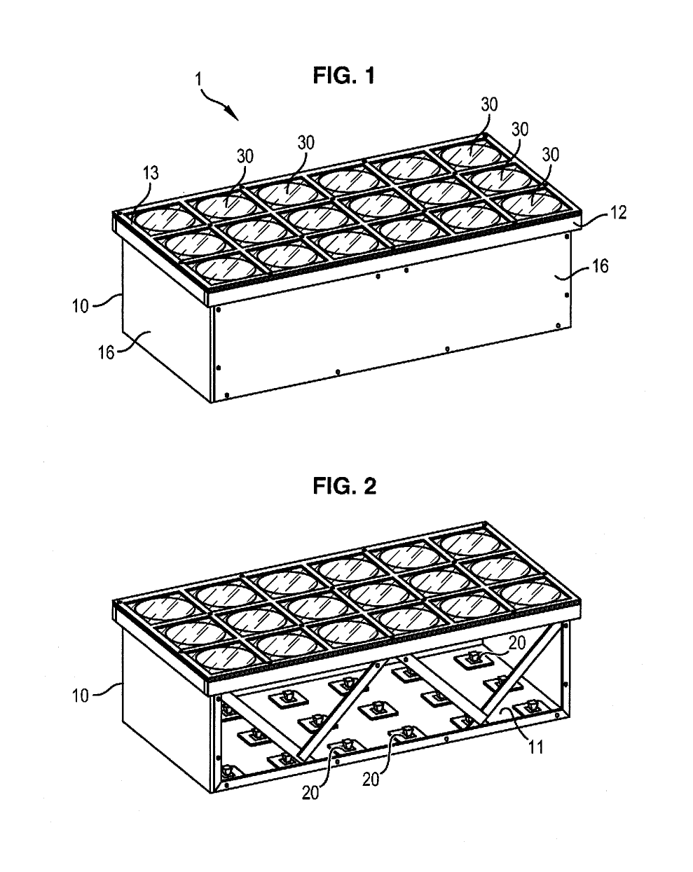

FIG. 1 illustrates an embodiment of a panel obtained according to the process of the invention;

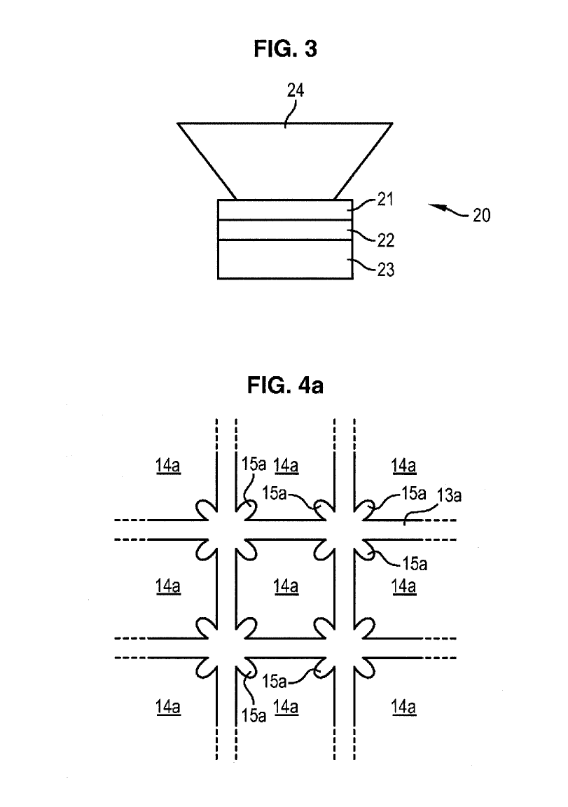

FIG. 2 illustrates the panel of FIG. 1, whereof one of the lateral walls has been removed to show its rear face;

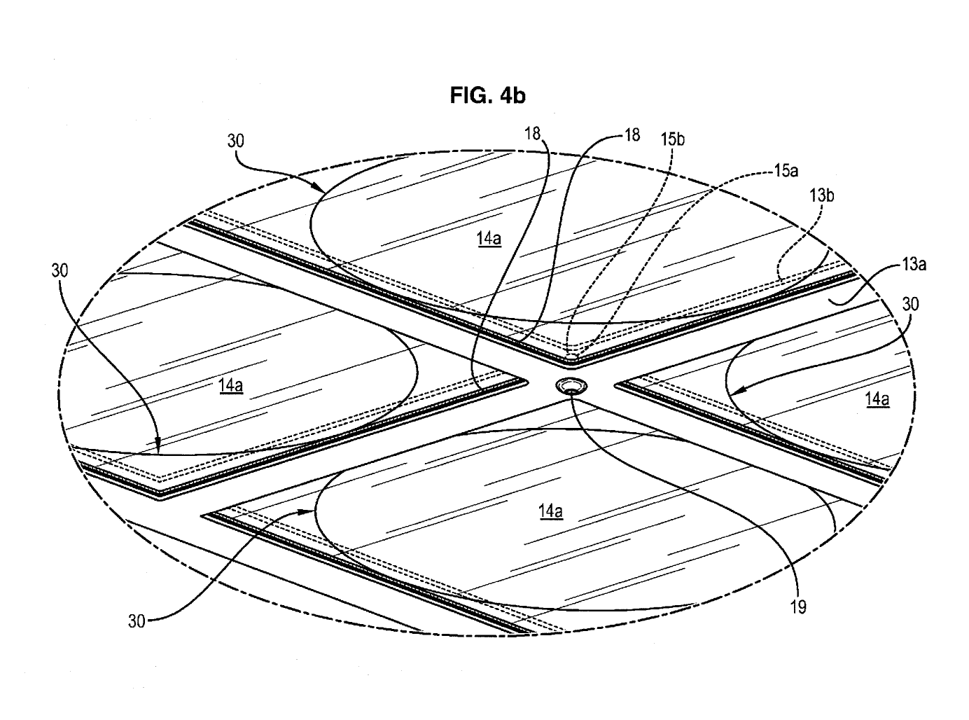

FIG. 3 is a profile view of a photovoltaic module which can be used in the panel of FIGS. 1 and 2;

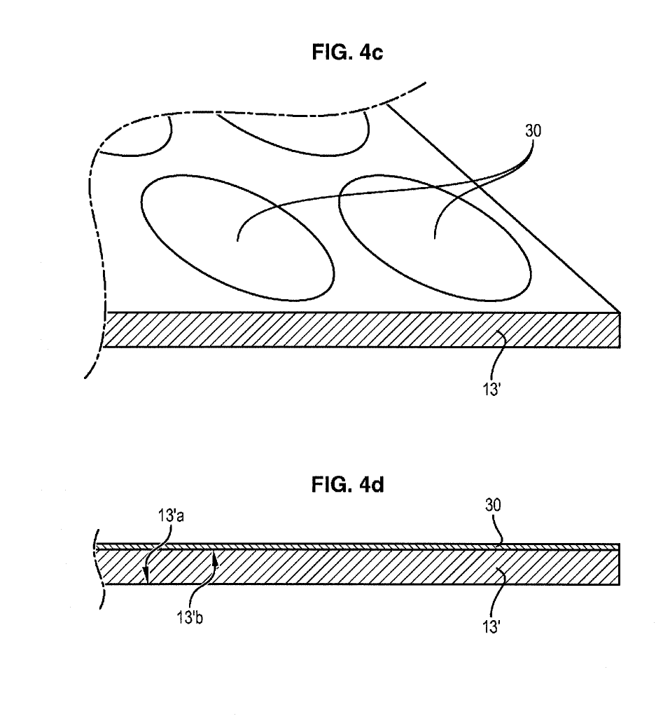

FIG. 4a is an enlargement of part of a first embodiment of a support adapted to keep in position the concentration systems and which can be used in the invention when viewed from the front;

FIG. 4b is an enlargement of the assembly of FIG. 4a viewed in elevation;

FIG. 4c is an enlargement of a second embodiment of a support which can be used in the invention, viewed in elevation;

FIG. 4d is a sectional view of FIG. 4c;

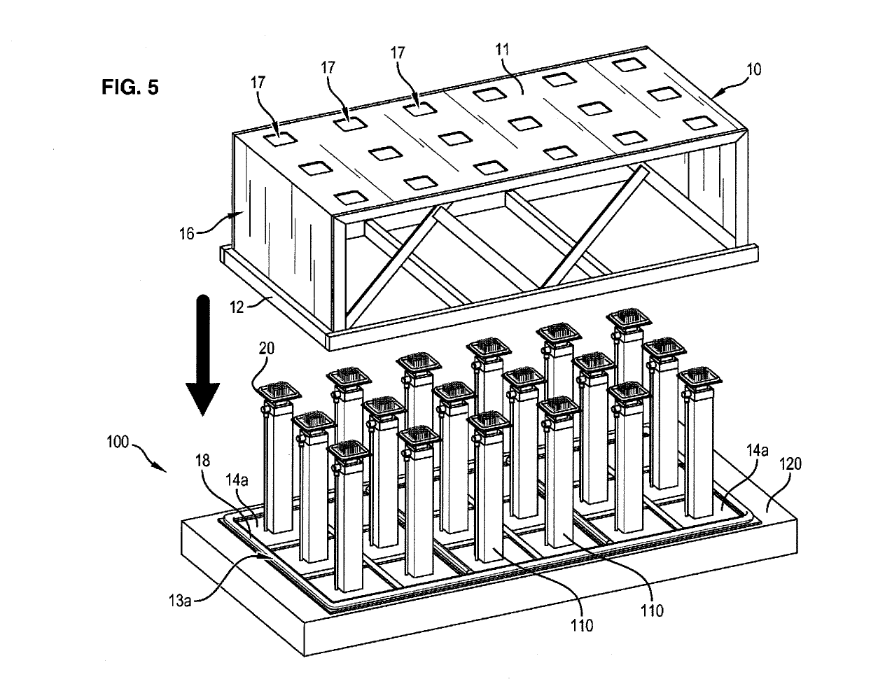

FIG. 5 illustrates a first embodiment of an assembly table and a panel on the point of being assembled according to the invention; and

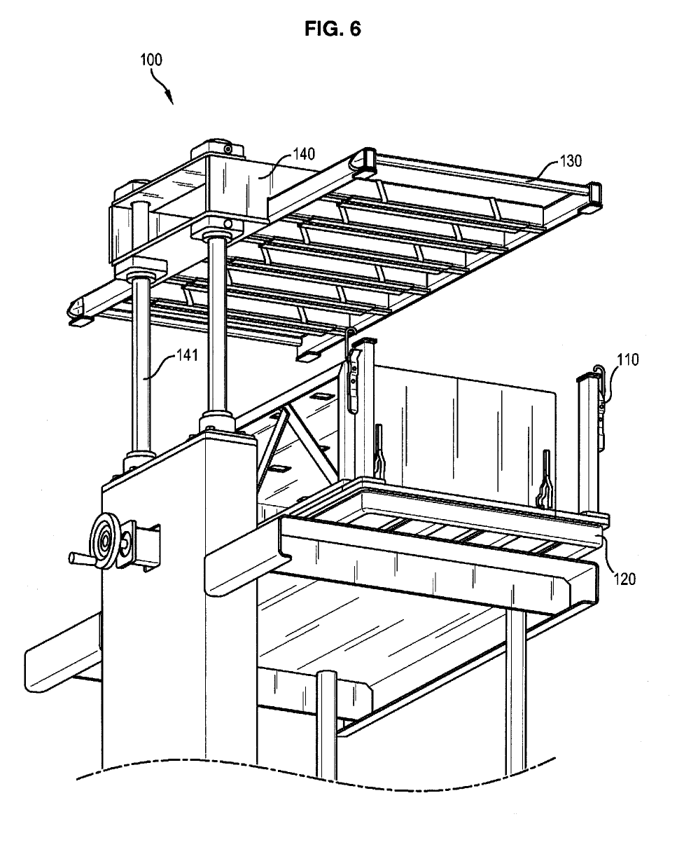

FIG. 6 illustrates a second embodiment of an assembly table according to the invention.

FIG. 1 illustrates a concentrated photovoltaic panel 1 according to the present invention.

The panel 1 the general form of a rigid parallelepiped rectangle whereof the length and width are for example of the order of a metre. It comprises a caisson 10 having a rear face 11 opposite an upper face or front face 12 in which is fixed a series of photovoltaic modules 20 and a series of light concentration systems 30 respectively.

The caisson 10 also comprises lateral walls 16, full or open, adapted to keep the front 12 and rear 11 faces at a fixed distance from each other and to close the caisson 10.

The photovoltaic modules 20 are conventional and can be of any type. They can especially comprise multi-junction cells 21, that is, highly effective cells comprising several thin layers each of which uses epitaxia by molecular jet to convert different parts of the solar spectrum and obtain better conversion outputs. For example, the multi-junction cells 21 are made by combining semi-conductors of germanium (Ge), gallium arsenide (GaAs), and gallium indium phosphide (GalnP2) type.

The photovoltaic modules 20 can be arranged either individually on the caisson, or grouped, in the form of flooring made up of individual modules joined together.

Each cell 21 is fixed, by adhesion or brazing for example, to a receiver 22, here ceramic, which is itself fixed to a dissipator 23. The dissipator 23 can especially be a copper sheet, aluminium sheet, or a radiator. The cell 21, the receiver 22 and the dissipator 23 are fixed by adhesion or brazing to the rear face 11 of the caisson 10 by means of a flange 24.

Light concentration systems 30 can especially be mirrors and/or lenses made of glass or plastic. Here, they are Fresnel lenses for example, which are arranged either individually on the caisson 10 or grouped in the form of flooring of individual lenses joined together. They can also be a film comprising concentration systems 30 obtained by injection of silicon. This latter embodiment is known to the person skilled in the art and will not be detailed further here.

The walls 11, 12 and 16 of the caisson 10 can be made from one or more materials as per the following conditions: rigidity, tightness, resistance to variations in temperature of between −50° C. and +100° C., and stability over time of these properties (that is, little or even no deformation over time). For this, the walls 11, 12 and 16 can undergo local or complete, chemical or thermal treatment, according to the material used, which can be plastic or metal material, for example.

According to a first embodiment, the front face 12 of the caisson 10 is made as for the rest of the caisson 10 of a thermo-lacquered treated aluminium alloy or of steel (especially galvanised steel), and is adapted to receive and keep the lenses 30 sealed.

For example, the front face 12 can support an assembly 13 formed by a lower frame 13a and an upper frame 13b (see FIGS. 4a and 4b). In FIGS. 4a and 4b, the frames 13a and 13b are open and each comprises a series of openings 14a, 14b designed to take up the lenses 30 and to spatially fix them in position relative to one another.

For lenses 30 of general rectangular form, the openings 14a and 14b are complementary rectangular in form.

For an individual Fresnel lens of dimensions 16.5×16.5 cm, made by reticulation of plastic film and a methyl polymethacrylate plate (PMMA), the arrow is of the order of 0.01 mm. Similarly, for lens flooring 30 comprising 3×2 individual lenses, the maximal arrow obtained is of the order of 0.03 mm.

The openings 14a of the lower frame 13a can also comprise, at the level of their ridges, in an ergot 15a intended to engage in an associated opening (not shown) made in the lens 30.

Each opening 14a preferably comprises at least two ergots 15a (see FIG. 4a) adapted to be inserted into two openings 15b (see FIG. 4b) of the lens (or of the lens flooring 30) which are associated thereto. The ergots 15a are preferably positioned on either side of the lens 30 to keep them in the plane of the assembly 13 and to limit its deformations in a plane normal to the latter. For example, for openings 14a and lenses 30 of general rectangular form, each opening 14a can comprise four centripetal ergots 15b arranged in its four corners (see FIG. 4).

As a variant, and by way of equivalent, the ergots 15a can extend from the lenses 30 (or lens flooring 30) to the lateral edges of the associated openings 14a, in which the openings are made.

Using such systems (ergots 15a and openings 15b) ensures proper positioning of the lenses 30 relative to the frames 13a and 13b irrespective of external conditions (temperature, humidity, etc.). For example, strong variations in temperature (especially between day and night in some regions of the globe, or according to seasons) can cause dilation or retraction of the lenses 30 within the opening 14 which is associated to them. The system of ergots and openings compensates deformations by acting as a guide for the lenses when they dilate by keeping their centre aligned with the photovoltaic modules irrespective of temperature, humidity, etc.

Each lens 30 can also be hermetically attached to at least one of the frames 13a and 13b, preferably to both, by means of a sealing joint 18, for example made of Ethylene Propylene Diene Monomer (EPDM) or Polyurethane (PU), and ensures tightness of the front face without restricting dilation of the lens 30. Because this step is conventional, it will not be described further here.

The assembly 13 formed by the frames 13a, 13b enclosing lenses 30 as per this embodiment is therefore robust and tight, due to the use of joints 18 at the interface with the lenses 30, ensuring negligible displacement of the centre of the lenses 30 (of the order of 0.2 mm for a lens of 169×169 mm) due to the presence especially of the ergots 15.

The frames 13a and 13b can also be fixed together, for example by means of screws 19.

In addition, the lenses can be assembled with the frames 13a and 13b according to conventional techniques, then taken to the assembly site, which both controls the environment in which the assembly 13 formed from the frames 13a and 13b and from the lenses 30 is assembled, and satisfies the internal tolerance criterion on the relative alignment and positioning of the lenses 30 relative to the frames 13a, 13b.

According to a second embodiment (illustrated in FIGS. 4c and 4d), the front face 12 of the caisson 10 does not support the assembly 13 composed of the frames 13a and 13b enclosing the lenses 30, but a glass plate 13′ whereof a lower face 13′a is covered by a silicon film comprising the concentration systems 30. This embodiment has the advantage of being easy to carry out from the industrial viewpoint and at the same time guarantees proper positioning of the concentration systems 30 relative to the plate 13′, their low clearance and the robustness of the assembly formed by the systems 30 and the plate 13′.

In this variant embodiment, the plate 13′ is not open. In addition, the silicon film comprising the concentration systems 30 is fixed on the lower face 13′a of the plate 13′, for example by reticulation.

The assembly 13 (respectively the plate 13′) formed in this way is intended to be applied and fixed to the front face 12 of the caisson 10, for example by means of screws and/or adhesion, tight joint, etc. during assembly of the caisson 10. For example, the lower part of the assembly (lower frame 13a comprising the ergots 15 or lower face 13′a of the plate covered by the silicon film) is applied to the front face 12 of the caisson 10, the upper frame 13b (respectively the upper face 13′b) being oriented outwards from the caisson 10.

Here, the front face 12 is an armature comprising four opposite and parallel sides forming a rectangle and intended to be fixed on the section of the lateral walls 16 of the caisson 10.

Finally, the rear face 11 also comprises openings 17 intended to receive the modules 20 (or module flooring 20).

A manufacturing process of a concentrated photovoltaic panel 1 according to the present invention will now be described. The general principle of the process consists of directly or indirectly aligning and positioning the photovoltaic modules 20 relative to the lenses 30 and to fix the elements making up the caisson 10 “around” the latter so as to optimise and ensure relative positioning of the modules 20 and lenses 30.

For this, the process according to the invention especially utilises an assembly table 100 adapted for directly or indirectly positioning the modules 20 relative to the lenses 30 and fixing the walls 16 and faces 11, 12 of the caisson 10 by adjusting them relative to the relative positioning of the modules 20 and lenses 30. The actual function of the assembly table 100 is to place and keep these elements 20, 30 in position in space during assembly such that it is the walls of the caisson 16, 11, 12 which are compelled to adapt to the position of the modules 20 and lenses 30, and not the inverse. This manufacturing method also limits costs relative to added costs engendered by an initial high quality of the caisson 10, rather by investing in the assembly table 100 which will be used for each assembly and capitalised on over time with the number of assembled panels 1.

According to a first embodiment illustrated in FIG. 5, the assembly table 100 comprises calibration feet 110, each adapted to receive a photovoltaic module 20 and a base 120 intended to receive the lower frame 13a.

The base 120 is preferably made of material having resistance to deformations greater than that of the front face 12 of the caisson 10 and of the frame 13a so as to compel the front face 12 to substantially adopt the form of the surface on which it is supported. For example, for a front face 12 made of aluminium alloy or plastic, the base 120 can be made of cast metal.

It is therefore important here to machine the surface of the base 120 which is intended to come into contact with the frame 13a precisely to the extent where this is what will determine the degree of tolerance of the final upper part of the panel (front face 12 and assembly 13).

The calibration feet 110 as such are fixed relative to the base 120 during assembling of the walls 16 and faces 11, 12 of the caisson 10 on the frame 13a. For example, they can be feet made of steel welded or fixed by any conventional technique on the basis of the assembly table, perpendicularly to the latter. The photovoltaic modules 20 are positioned on the free end of the feet 110, either manually or automatically by means of racks or any other conventional technique.

To make is easy for the modules 20 to be held by the feet, the contact surface between the feet and the modules 20 can be machined.

The relative dimensions and positioning of the calibration feet 110 relative to the base 120 are such that when the modules 20 are placed on the free end of said feet 110 and the frame 13a is placed on the base 120, the modules 20 are arranged in the focal centre of the lens 30 which will be associated with the latter.

It is important to note that at this stage of the process, the lenses 30 are generally not yet mounted on the lower frame 13a, especially if the feet 110 are fixed to the base 120, because the feet pass through the openings 14a of the frame 13a. But, as was evident earlier, the upper frame 13b and the lenses 30 can be mounted and fixed in position on the lower frame 13a with great precision, here of the order of 0.1 mm. As a consequence, by spatially positioning the modules 20 relative to the lower frame 13a by means of the base 120 and the calibration feet 110, the modules 20 are being positioned indirectly relative to the lenses 30, given that the position of the lenses 30 is determined relative to said lower frame 13.

An adjustment joint is applied to the part of the lower frame 13a which is intended to be supported on the front face 12 of the caisson 10 and/or on the front face 12.

The front face 12 and the lower frame 13a are preferably dedusted and degreased prior to their assembly to improve their adhesion and the quality of the resulting panel 1.

The adjustment joint can be a structural adhesive of adhesion type based on methacrylate, polyurethane or epoxy, mono- or bi-components, or a joint based on elastomers (mastic silicon (MS) polymers). According to the joint selected, the process can optionally comprise an extra treatment step of the surface to which it is applied.

The quantity of joint applied can also vary according to the type of joint selected. For example, for a structural joint, a thin strip of a thickness less than or equal to a millimetre is preferably applied, and of a width between environ eight and ten millimetres, while for an elastomer-based joint a thicker layer is applied (at least three or four millimetres).

Finally, the front face 12 of the caisson 10 is applied under determined pressure and temperature and over a period adapted to the joint selected to the lower frame 13a, and is kept in position relative to one another until the adjustment joint has fully dried.

The function of the adjustment joint is to absorb the imperfections of the lateral walls 16 and of the front face 12 and of the lower frame 13a (local undulations, surface irregularities, insufficiently precise dimensions, etc.) by congealing. The modules 20, which are kept in position by the calibration feet 110, can stay precisely spatially aligned relative to the lower frame 13a since the caisson 10 is compelled to conform to their respective position by the joint. This joint therefore advantageously absorbs a wide range of manufacturing and alignment defects of the caisson 10, and therefore reduces the initial cost of the caisson used since alignment tolerances are more flexible.

The rear face 11 can be fixed to the lateral walls 16 prior to or after their assembly with the front face 12.

Advantageously, an adjustment joint is also applied to the periphery of all or some of the openings 17 and/or modules 20 such that fixing the modules 20 to the rear face 11 is done also by compensating and smoothing out the manufacturing defects of the different parts of the caisson 10.

It is quite evident that the process according to the invention pushes the caisson 10 to adapt to the relative positioning of the modules 20 and the lenses 30 by keeping their relative position fixed, throughout the assembly procedure of the walls 16 and faces 11, 12 of the caisson 10.

According to a second embodiment illustrated in FIG. 6, the assembly table 100 comprises a calibration chassis 130 adapted to bear the photovoltaic modules 20 and a base 120, similar to the base of the first embodiment, intended to receive the front face 12 of the caisson 10.

This second embodiment can be deployed regardless in the event where the support 13, 13′ intended to receive and hold the concentration systems 30 is the assembly 13 (frames 13a and 13b enclosing the lenses 30) or the glass plate 13′ on which the silicon film serving as concentration systems 30 is laminated.

Throughout this description, the second embodiment of the process will be described in relation to the assembly on the caisson 10 of the frames 13a and 13b enclosing the lenses 30. This is not however limiting and can be applied mutatis mutandis to the plate 13′ fitted with the silicon film. The role of the lower frame 13a will be taken by the lower face 13′a of the plate 13′ on which the silicon film comprising the concentration systems 30 has been previously fixed, while the role of the upper frame 13b will be taken by the upper face 13′b of the plate which is oriented to the outside of the caisson 10.

The chassis 130 is mounted here on a mobile support 140 between a first position, in which the photovoltaic modules 20 are put in place on the chassis 130 relative to each other, and a second position, in which the modules 20 are positioned relative to the lenses 30 by means of the assembly table 100.

The second position can for example be determined with precision by way of calibration means 110 intended to receive the chassis 130 fitted with the photovoltaic modules 20. These calibration means 110 can especially be feet fixed on the base 120, as in the first embodiment, and can fix the distance separating the base 120 from the chassis 140 when the latter is in the second position.

In this way, the photovoltaic modules 20 are on the one hand positioned relative to each other on the calibration chassis 130, and on the other hand relative to the lenses 30 by means of the calibration feet 110 whereof the height is such that the modules are separated from the lenses by a distance equal to the focal distance of said lenses when the chassis is in the second position.

Again, the base 120 is preferably made of material having greater resistance to deformations than that of the front face 12 of the caisson 10 so as to compel the front face 12 and the assembly 13 to substantially adopt the form of the surface on which it is supported. For example, for a front face 12 made of aluminium alloy or plastic, the base 120 can be made of cast metal.

In this embodiment, the front face 12 of the caisson 10 is not placed directly on the base 120, but rather the assembly 13 formed by the frames 13a and 13b and the lenses 30. For this, the assembly 13 is positioned precisely on the base 120 and relative to the calibration feet 110. An adjustment joint (such as that described earlier in relation to the first embodiment) is then placed on the lower frame 13a and/or on the front face 12, then the caisson 10 (already including the walls 16 and faces 11 and 12 assembled) are applied to the lower frame 13a.

At this stage this produces a caisson 10 whereof the upper face (i.e. the assembly 13 applied to the front face 12) is complete and comprises lateral walls 16 and a rear face 11.

Before the adjustment joint is attached, the photovoltaic modules 20 is applied by positioning the calibration chassis 130 relative to the calibration feet 110, for example by translation along guides 141 of the chassis 130 between the first position and the second position (in which the chassis 130 can especially rest on the feet 110). In summary here:
on the one hand, the lenses 30 are positioned relative to one another on the base 120, but also relative to the base 120 itself and to the calibration feet 110, and
on the other hand, the modules 20 are positioned relative to each other and relative to the chassis 130.

So, as the chassis 130 is put in position in space precisely and determined relative to the calibration feet 110 due to the support 140, the assembly table 100 positions in space the photovoltaic modules 20 relative to the lenses 30.

Of course, the role of the calibration feet 110 can be taken by a position detector of the chassis 130 relative to the base, a stop on the guides of the chassis 130, or any equivalent means for spatially positioning the calibration chassis 130 supporting the modules 20 relative to the base 120.

As a variant embodiment, the chassis 130 supporting the photovoltaic modules 20 is fixed and the base 120 supporting the caisson 10 is assembled to the assembly 13 is mobile: it is the base 120 and the calibration feet 110 which are shifted relative to the chassis 140.

Advantageously, an adjustment joint is also applied to the part of the photovoltaic modules 20 which is intended to come into contact with the caisson 10 and/or on the periphery of the openings 17 of the rear face 11 to enable better adaptation of the caisson 10 to the relative positioning of the modules 20 and of the lenses 30.

The resulting panel 1 therefore has the following advantages: it is robust and tight, because of using the walls 16 and face 11, 12 made of adapted materials such as aluminium alloys or plastics, as well as joints especially guaranteeing tight sealing between the elements making up the caisson 10, the modules 20 and lenses 30. In addition, the modules 20 are positioned precisely in the focal centre of the lenses 30, such that a majority of the light flow is transmitted by the lenses 30 to the modules 20.

According to a variant embodiment, the chassis 130 positions not the photovoltaic modules 20 on the rear face 12 already assembled with the lateral walls 16 of the caisson 10, but the rear face 12 pre-fitted with the modules 20 on the lateral walls of the caisson 10. For this, the process of the invention comprises the following steps:
fixing as is known the concentration systems 30 on the front face 12 relative to a reference point,
simultaneously or at some other time, fixing the photovoltaic modules 20 on the rear face 11, given the position of the concentration systems 30 relative to the reference point, then
placing the chassis 130 in the first position and positioning the rear face 11 fitted with the modules in position on the chassis 130 relative to the base 120 and relative to the front face 12 and to the concentration systems 30, and
bringing the chassis 130 to its second position so as to fix the photovoltaic modules 20 in position relative to the concentration systems by means of positioning the rear face 11 relative to the base and to the front face 12, in keeping with the process of the invention.

It is evident of course that the invention also covers the embodiment in which the rear face fitted with the photovoltaic modules 20 is first positioned on the chassis, then the lenses are positioned on the front face 12, while the modules 20 and the lenses 30 are put in position relative to each other by means of the chassis 130, of the base 120 and/or a common reference point.

When the concentration systems 30 are lenses obtained by injection of a silicon film arranged on the lower face 13′a of the glass plate 13′ (caisson side), the lower face of this glass plate 13′ is advantageously fixed to the front face 12 prior to positioning of the front face 12 relative to the rear face 11, for example by adhesion. In addition, in this embodiment, the silicon film 30 is preferably arranged at a distance from the edges of the glass plate 13′ such that only the glass plate 13′ is in contact with the lateral walls 16 of the caisson 10.

The process of the invention can comprise variant embodiments as a function of the materials making up the caisson 10 and the rear face 11. In fact, according to the materials used the caisson 10 can be made in a single piece, especially when it is made of plastic, or by assembly of several elements, for example with rivets and/or adhesion.

According to a variant embodiment, the caisson 10 is made of plastic of the thermosetting type (such as charged polybutylene tetraphthalate, charged polyethylene, etc.).

It is then possible to make the front 12 and rear 11 faces as well as the lateral walls 16 in a single piece, for example by injection, then separate the rear face 11 from the walls 16 to then insert or apply the concentration systems 30 and the photovoltaic modules 20 respectively.

As the panel 1 is being made, the front face 12, which is in a single piece with the lateral walls 16, is placed on the base 120, then the rear face fitted with the photovoltaic modules 20 is brought back because of the chassis.

This embodiment has various advantages.

First of all, thermosetting materials are easier to process and give greater confidence than aluminium or steel. In addition, using such material limits potential misalignments due to concentrated energy flows during use of the panel 1.

In addition, assembling the faces 11, 12 and 16 of the caisson in one piece ensures their proper correspondence and their complementarity during reassembly of the rear face 11 with the rest of the caisson 10, at the same time boosting production rates of the panels 1, the latter not being delayed by manual assembly steps. The advantages of making this in one piece in particular is when the panel 1 is of moderate size, that is, of the order of a metre.

Finally, with the precise positioning of the concentration systems 30 relative to the front face 12 known, this embodiment positions the photovoltaic modules 20 relative to the rear face 11. All that needs to be done now is position the rear face 11 relative to the front face 12 on the assembly table 100.

The photovoltaic modules 20 relative to the lenses 30 can be positioned on different sites using the same tool. It is therefore very simple and pertinent to make them close to the installation site of the panel 1.

According to a second variant embodiment, only the lateral walls 16 and the front face 12 are made in a single piece of thermosetting material (such as charged polybutylene tetraphthalate, charged polyethylene, etc.), the rear face 11 being made of different material (for example of metal) or similar, then attached to the lateral walls 16 (after positioning of the photovoltaic modules 20) by the chassis 130 on the assembly table 100.

The rear face 11 is preferably made of thermo-lacquered aluminium alloy or steel. It is then fixed to the lateral walls by means of rivets and/or adhesion, for example silicon-based adhesion.

Finally, according to a final variant, all the walls 11, 12 and 16 of the caisson 10 are made of metal, such as thermo-lacquered aluminium alloy or steel. The front face 12 and the lateral walls 16 are assembled together, especially by rivets and/or adhesion before being placed on the base 120, then the rear face 11 pre-fitted with the photovoltaic modules 20 is put in position relative to the base 120 and to the front face 12 by means of the chassis 130 before being assembled onto the lateral walls 16. This variant embodiment is however costlier than making the panel 1 from thermosetting materials (such as charged polybutylene tetraphthalate, charged polyethylene, etc.) only, due especially to the necessary processing of the metals used.

It is also evident that the process does not require a strict environment in which to be carried out, with the steps generally being taken in a clean room (such as making the modules) having been taken previously. It is therefore possible to assemble the panels 1 in situ (that is, on the module manufacturing site, etc.) or at a distance (for example on the installation site of the panel, or near the latter) by providing the modules (made in a clean room), the lenses 30, the walls 16, the open frames 13a and 13b and the front face 12.

1. A manufacturing process for a concentrated photovoltaic panel (1), said panel (1) comprising:
a rear face (11) adapted for fixing in position a series of photovoltaic modules (20);
a front face (12),
a lower part (13a, 13′a) of a support (13, 13′), fixed on the front face, said support (13, 13′) being adapted to fix in position a series of light energy concentration systems (30), such that each concentration system (30) is aligned with at least one photovoltaic module (20) which is associated thereto; and
lateral walls (16), connecting the rear face (11) and the front face (12) so as to define a closed caisson (10);
the process being characterised in that the respective position of the photovoltaic modules (20) is spatially fixed relative to the lower part (13a) of the support (13, 13′) when the front face (12), the lateral walls (16) and the rear face (12) of the caisson (10) are assembled with the photovoltaic modules (20) and the lower part (13a, 13′a) of the support (13, 13′).

2. The manufacturing process as claimed in claim 1, in which:
the photovoltaic modules (20) are spatially positioned relative to each other and relative to the lower part (13a, 13′a) of the support (13, 13′); and
the front face (12) is assembled with the lower part (13a, 13′a) of the support (13, 13′) on the one hand, and the rear face (11) with the photovoltaic modules (20) on the other hand by keeping the photovoltaic modules (20) spatially positioned relative to the position of the concentration systems in the lower part (13a, 13′a).

3. The process as claimed in any one of claims 1 and 2, characterised in that it further comprises application of a adjustment joint in one of the zones of the following group:
between all or some of the photovoltaic modules (20) and the rear face (11) of the caisson (10),
between the rear face (11) of the caisson (10) and the flanks of the caisson (10),
between the front face (12) of the caisson (10) and the lower part (13a, 13′a).

4. The process as claimed in any one of claims 1 to 3, characterised in that it also comprises a subsequent step for fixing the light concentration systems (30) on the lower part (13a, 13′a).

5. The process as claimed in any one of claims 1 to 4, characterised in that the support (13′) is a plate (13′) made of glass on which is fixed a film comprising the concentration systems (30), and in that the lower part is the lower face (13′a) of said plate.

6. The process as claimed in any one of claims 1 to 5, characterised in that the photovoltaic modules (20) are spatially fixed and positioned relative to the lower part (13a, 13′a) of the support (13, 13′) by:
positioning of the lower part (13a, 13′a) of the support (13, 13′) on a base; and
positioning of the modules (20) on calibration feet (110), each calibration foot (110) being kept fixed relative to the base (12) during application of the front face (12) on the lower part (13a, 13′a) and arranged such that when the concentration systems (30) are mounted on the lower part (13a, 13′a) the photovoltaic modules (20) are in their respective focal centre.

7. The process as claimed in claim 6, characterised in that the photovoltaic modules (20) are spatially positioned and relative to the lower part (13a, 13′a) by:
positioning of the lower part (13a, 13′a) of the support (13, 13′) on a base (120); and
positioning of the modules (20) on a calibration chassis (130), the calibration chassis (130) itself being put in position relative to the base (120) and arranged such that when the faces and lateral walls (11, 12, 16) of the caisson (10) are assembled with the modules (20) and the lower part (13a, 13′a) of the support (13, 13′) the photovoltaic modules (20) are in the respective focal centre of said concentration systems (30).

8. The process as claimed in claim 7, in which the photovoltaic modules (20) are fixed on the rear face (11) of the caisson (10) before being positioned on the calibration chassis (130).

9. The process as claimed in any one of claims 7 and 8, also comprising a step for fixing the concentration systems (30) on the lower part (13a, 13′a) of the support (13, 13′) prior to positioning of said lower part (13a, 13′a) on the base (120).

10. The process as claimed in claim 9, also comprising the positioning of the chassis (130) relative to the base (120) by means of at least one calibration foot (110).

11. A mounting table (100) for manufacturing a concentrated photovoltaic panel (1), the panel (1) comprising:
a rear face (11) adapted to fix in position a series of photovoltaic modules (20);
a front face (12), supporting a lower part (13a, 13′a) of a support (13, 13′); and
lateral walls (16) connecting the rear face (11) and the front face (12) so as to define a closed caisson (10);
the assembly table comprising:
a base (120) adapted to receive the lower part (13a, 13′a) of the support (13, 13′), and
calibration means (110, 130, 140) intended to receive and keep in position the photovoltaic modules (20) relative to the lower part (13a, 13′a) of the support (13, 13′),
and being characterised in that the calibration means (110, 130, 140) are spatially positioned relative to the base (120) during assembly of the lateral walls and faces (11, 12, 16) of the caisson (10) with the photovoltaic modules (20) and the lower part (13a, 13′a).

12. The mounting table (100) as claimed in claim 11, characterised in that the calibration means comprise a chassis (130), calibration feet (110) and a mounting support (141), the calibration feet and the mounting support being adapted to position the chassis (130) relative to the base (120).

13. The mounting table (100) as claimed in claim 12, in which the chassis (130) is adapted to receive the rear face (11) of the caisson (10) pre-fitted with the photovoltaic modules (20), while the base (120) is adapted to receive the front face (12).

14. The mounting table (100) as claimed in any one of claims 11 to 13, characterised in that the base (120) exhibits resistance to deformations greater than that of the front face (12) and of the lower part (13a, 13′a).

15. The mounting table (100) as claimed in any one of claims 11 to 14, characterised in that the calibration feet (110) are fixed on the base (120).
